(19) United States
(12) Patent Application Publication
(10) Pub. No.: US 2018/0335472 A1
(43) Pub. Date: Nov. 22, 2018

(54) INNER FAN MOUNTED BURN-IN TESTER

(71) Applicant: JST Co., Ltd., Yongin-si (KR)

(72) Inventors: Hack Won HWANG, Yongin-si (KR); Min Ho Jeon, Osan-si (KR)

(21) Appl. No.: 15/953,511

(22) Filed: Apr. 16, 2018

(30) Foreign Application Priority Data
May 17, 2017 (KR) 10-2017-0060892

(51) Int. Cl. G01R 31/28

(52) U.S. Cl. CPC G01R 31/2877

(57) ABSTRACT

The present invention relates to a burn-in tester, and according to one aspect of the present invention, there is provided a burn-in tester comprising: a board chamber provided to accommodate a test board; a test chamber having an accommodation space for accommodating a tester substrate, a first side surface forming the accommodation space and a second side surface opposite to the first side surface, which is provided such that the air introduced into the accommodation space through the first side surface passes through the accommodation space to be discharged out of the accommodation space through the second side surface; a blowing unit located on the first side surface side of the test chamber and including a plurality of blast fans for generating an air flow from the first side surface side to the second side surface side; and a temperature control unit provided to control the temperature in the test chamber using a refrigerant circulation cycle and equipped with an evaporator located on the second side surface side of the test chamber.

### RELATED APPLICATION

This application claims the benefit of priority of Korean Patent Application No. 10-2017-0060892 filed May 17, 2017, the contents of which are incorporated herein by reference in their entirety.

### FIELD AND BACKGROUND OF THE INVENTION

The present invention relates to a burn-in tester, and particularly relates to a burn-in tester which is capable of precisely controlling a temperature of a test chamber and has a cryogenic control temperature zone of −50° C. to +150° C. in particular.

In general, a burn-in tester is a device that tests reliability of a packaged semiconductor device for thermal stress when powering and operating the semiconductor device.

Recently, the burn-in tester is manufactured to perform an operation test of the semiconductor device together with the existing burn-in test.

FIGS. 1 and 2 are views showing a general burn-in tester (1).

The burn-in tester (1) comprises a board chamber (not shown) in which a semiconductor device is accommodated and a test chamber (20) in which a tester substrate is accommodated.

On the other hand, the test chamber (20) should be adjusted to a very low temperature (about −40° C.) state during operation, and prevent unnecessary heat source inflow and heat discharge to the outside in order to maintain the temperature inside the test chamber uniformly.

Also, the conventional burn-in tester comprises a blast fan (30) provided at the upper part, where the blast fan (30) is provided to perform a function to regulate the temperature in the test chamber (20) by generating air circulation in the test chamber (20).

Generally, the blast fan (30) comprises a motor part and a fan part. At this time, the motor part is disposed outside the test chamber, and the blast fan (30) is located inside the test chamber (20). The motor part transmits rotational force to the fan part, and the fan part comprises a plurality of blades and generates an air flow depending on the rotation of the blades.

On the other hand, the conventional blast fan had a problem that it is difficult to uniformly maintain the temperature in an accommodation space of the test chamber (20). However, it is important that since the test is performed in a state where the test chamber (20) is inserted with a plurality of tester boards, all the temperatures of the regions where each tester board is inserted are maintained the same during the test.

### SUMMARY OF THE INVENTION

It is a problem to be solved by the present invention to provide a burn-in tester capable of individually controlling temperatures of a plurality of regions in a test chamber accommodating space.

Also, it is a problem to be solved by the present invention to provide a burn-in tester capable of maintaining temperatures of a plurality of regions in a test chamber accommodating space the same.

Furthermore, it is a problem to be solved by the present invention to provide a burn-in tester having a cryogenic control temperature zone of −50° C. to +150° C.

To solve the above-described problems, according to one aspect of the present invention, there is provided a burn-in tester for testing a semiconductor device loaded on a test board, which comprises a board chamber, a test chamber, a blowing unit and a temperature control unit.

The burn-in tester comprises a board chamber provided to accommodate a test board. Also, the burn-in tester comprises a test chamber having an accommodation space for accommodating a tester substrate, a first side surface forming the accommodation space and a second side surface opposite to the first side surface, which is provided such that the air introduced into the accommodation space through the first side surface passes through the accommodation space to be discharged out of the accommodation space through the second side surface. Furthermore, the burn-in tester comprises a blowing unit located on the first side surface side of the test chamber and including a plurality of blast fans for generating an air flow from the first side surface side to the second side surface side. In addition, the burn-in tester comprises a temperature control unit provided to control the temperature in the test chamber using a refrigerant circulation cycle and equipped with an evaporator located on the second side surface side of the test chamber.

As described above, the burn-in tester related to one embodiment of the present invention has the following effects.

By disposing the blowing unit equipped with a plurality of blast fans on one side (first side surface) of the test chamber and disposing the evaporator on the other side (second side surface) of the test chamber, the temperatures of the plurality of regions in the test chamber accommodating space can be controlled individually. Furthermore, the temperatures of the plurality of regions in the test chamber accommodating space can be maintained the same.

In addition, the temperature control unit has a cryogenic control temperature zone of −50° C. to +150° C.

Besides, an increase in pressure at a high temperature can be prevented through an expansion tank, a cooling capacity can be proportionally controlled in response to a heat load in a chamber through an electronic automatic expansion valve (hereinafter, also referred to as an electronic expansion valve), and it is possible to prevent a freezer from becoming hot upon high temperature operation or a freezing phenomenon upon low temperature operation.

Also, by controlling the cooling capacity, there is no need to use a high-capacity heater, so that the consumed power can be reduced; since it is controlled linearly depending on a heat load size, a stable time (overshoot, undershoot) of the temperature control can be shortened upon temperature increase and decrease; precision temperature control can be realized; and cooling efficiency can be improved.

### BRIEF DESCRIPTION OF THE SEVERAL VIEWS OF THE DRAWINGS

FIGS. 1 and 2 are views showing a general burn-in tester.

FIG. 3 is a schematic view showing a blowing unit constituting a burn-in tester related to one embodiment of the present invention.

FIG. 4 is a front view of the blowing unit shown in FIG. 3.

FIG. 5 is a configuration diagram of a temperature control unit constituting a burn-in tester.

### DESCRIPTION OF SPECIFIC EMBODIMENTS OF THE INVENTION

Hereinafter, a burn-in tester according to one embodiment of the present invention will be described in detail with reference to the accompanying drawings.

In addition, the same or similar reference numerals are given to the same or corresponding components regardless of reference numerals, of which redundant explanations will be omitted, and for convenience of explanation, the size and shape of each constituent member as shown may be exaggerated or reduced.

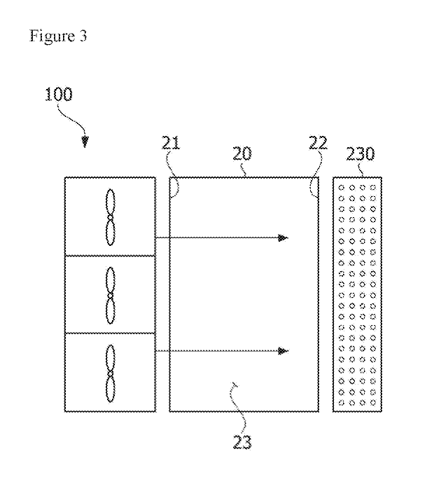

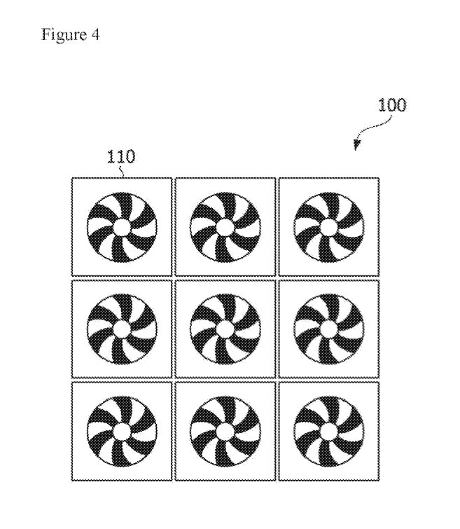

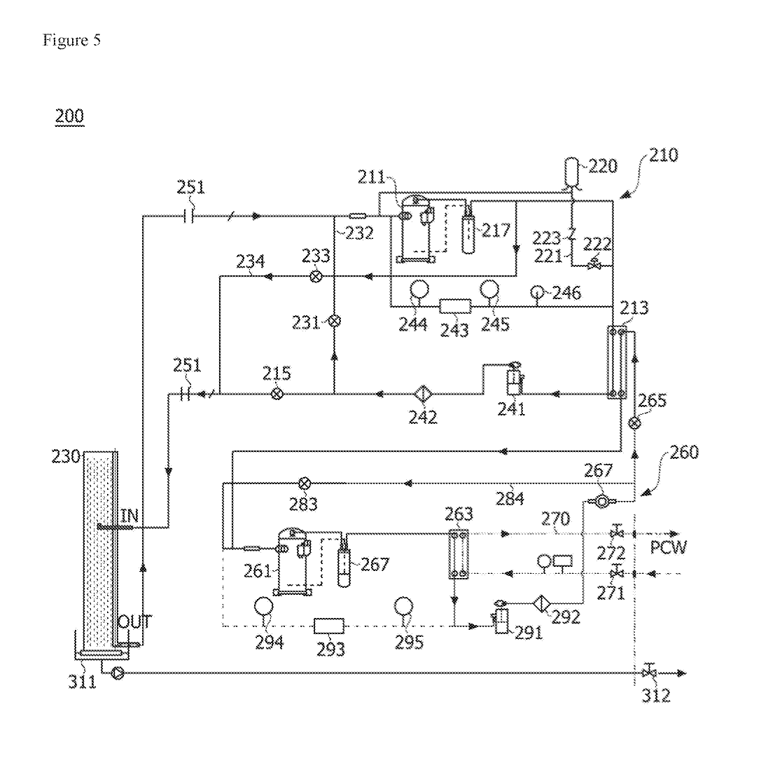

FIG. 3 is a schematic view showing a blowing unit (100) constituting a burn-in tester related to one embodiment of the present invention, FIG. 4 is a front view of the blowing unit (100) shown in FIG. 3, and FIG. 5 is a configuration diagram of a temperature control unit (200) constituting a burn-in tester.

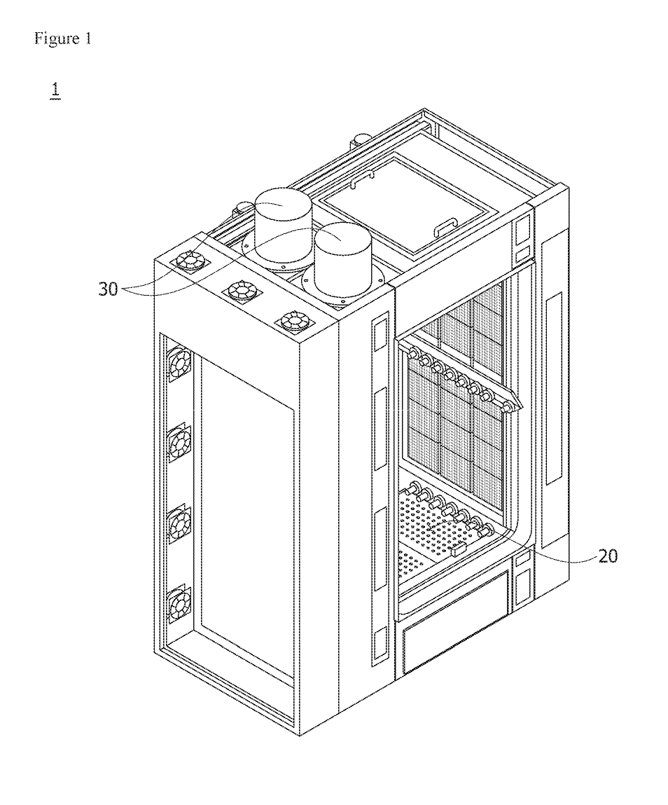

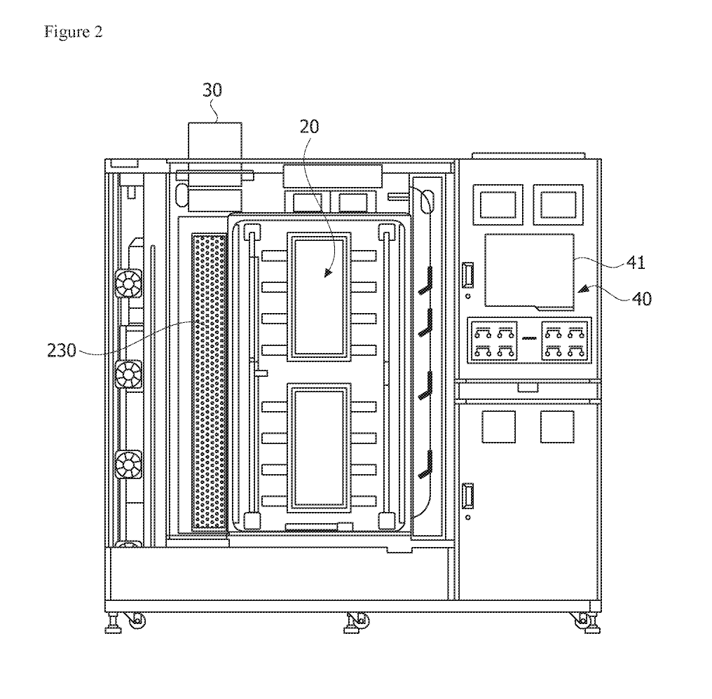

The configuration of the test chamber (20), the control part (40) and the control panel (41) of the burn-in tester (1) described with reference to FIGS. 1 and 2 is also applicable to the burn-in tester of the present invention, and thus it will be explained by using FIGS. 1 and 2, and the corresponding reference numerals as they are.

In addition, in the present invention, while the blast fan of the reference numeral 30 is used as it is, the blowing unit (100) may also be used together, and alternatively, only the blowing unit (100) may also be used, with removing the blast fan (30) of FIG. 1.

Referring to FIGS. 1 and 3, according to one aspect of the present invention, there is provided a burn-in tester for testing a semiconductor device loaded on a test board, which comprises a board chamber (not shown), a test chamber (20), a blowing unit (100) and a temperature control unit (200).

The burn-in tester related to one embodiment of the present invention comprises a board chamber provided to accommodate a test board.

Also, the burn-in tester comprises a test chamber (20) having an accommodation space (23) for accommodating a tester substrate, a first side surface (21) forming the accommodation space (23) and a second side surface (22) opposite to the first side surface (21), which is provided such that the air introduced into the accommodation space (23) through the first side surface (21) passes through the accommodation space (23) to be discharged out of the accommodation space (23) through the second side surface (22).

Specifically, the burn-in tester related to one embodiment of the present invention is a burn-in tester for testing a semiconductor device loaded on a test board using a tester substrate. The burn-in tester is equipped with a board chamber (also referred to as a ‘burn-in chamber’) for accommodating semiconductor devices, and a test chamber (20) in which a tester substrate for reading a result signal feeding back after applying a test signal to the semiconductor devices is accommodated.

At this time, the tester board enters the board chamber, and the tester substrate enters the test chamber (20). In addition, the burn-in tester may comprise a contact device (not shown) provided to electrically connect the semiconductor device of the test board to the tester substrate by contacting the test board accommodated in the board chamber with the tester substrate. For example, the contact device may also be constituted by a contact device disclosed in Korean Patent No. 10-1676774 of the present applicant. The contact device moves the test board in a state holding the test board through a holding plate to perform a function to connect a connector of the test board to a connector of the tester board.

Furthermore, the burn-in tester comprises a blowing unit (100) located on the first side surface (21) side of the test chamber (20) and including a plurality of blast fans (110) for generating an air flow from the first side surface (21) side to the second side surface (22) side. Also, the plurality of blast fans (110) may be arranged along the width direction and the height direction of the first side surface (21) of the test chamber (20). In addition, the plurality of blast fans (110) may be continuously arranged along the width direction and the height direction of the first side surface (21) and two adjacent blast fans (110) may also be arranged apart at a predetermined interval along the width direction and the height direction of the first side surface (21). Also, the two adjacent blast fans (110) may be arranged so that housings of the respective blast fans (110) contact with each other along the width direction and the height direction of the first side surface (21).

In addition, at least two blast fans (110) in the blowing unit (100) are provided at different positions along at least one direction of the width direction and the height direction of the first side surface (21). Furthermore, the blowing unit (100) may comprise a plurality of temperature sensors, which are each disposed to measure temperatures of a plurality of different regions in the accommodation space (23). At this time, the plurality of blast fans (110) are provided to be individually controlled according to the measurement results of the plurality of temperature sensors. The rotation speed of the individual blast fan (110) can be adjusted by the control part (40). For example, the rotation speed of the blast fan according to the temperature in the chamber (20) may be previously stored in a memory in the form of a simplified chart, where the control part (40) may adjust the rotation speed of the blast fan (110) corresponding to the relevant region (air is discharged to the relevant region) depending on the temperature according to each region of the accommodation space in the chamber.

Referring to FIG. 5, the burn-in tester comprises a temperature control unit (200) provided to adjust the temperature in the test chamber (20) using a refrigerant circulation cycle and equipped with an evaporator (230) located on the second side surface (22) side of the test chamber (20).

Besides, the temperature control unit (230) may have a cryogenic control temperature zone of −50° C. to +150° C.

Referring to FIG. 5, the temperature control unit (200) comprises a first cooling part (210) through which a first refrigerant circulates and a second cooling part (260) through which a second refrigerant circulates.

Specifically, the first cooling part (210) comprises a first compressor (211) for compressing the first refrigerant discharged from the discharge end (OUT) of the evaporator (230), a first condenser (213) to which the first refrigerant passing through the first compressor (211) is introduced, and a first electronic expansion valve (215) positioned between the first condenser (213) and the inflow end (IN) of the evaporator (230). The first electronic expansion valve (215) is controlled proportionally depending on the heat load in the test chamber (20) by the control part (40) as described above.

Also, the first cooling part (210) is provided such that the first refrigerant discharged from the first condenser (213) and passing through the first electronic expansion valve (215) is introduced into the inflow end (IN) of the evaporator (230).

Furthermore, the first cooling part (210) may comprise a first branch line (221) branched between the first compressor (211) and the first condenser (213) and connected to the inflow end side of the first compressor (211).

The first branch line (221) may be provided with an expansion tank (220) that the first refrigerant discharged from the first compressor (211) is introduced and stored and one or more valves (222, 223) provided at the inflow end side of the expansion tank (220), respectively. For example, a first solenoid valve (222) and a check valve (223) may be each sequentially provided in the first branch line (221) along the direction where the first refrigerant is introduced into the expansion tank (220). In addition, a capillary is provided on the discharge end side of the expansion tank (220), so that retention of the first refrigerant can be induced in the expansion tank (220). That is, if the pressure increases to a high pressure at a high temperature (for example, 100° C. or higher), the control part (40) may open the first solenoid valve (222) to bypass the first refrigerant discharged from the first compressor (211) to the expansion tank (220)). Accordingly, if the pressure increases, the first refrigerant may be dispersed in the expansion tank (220) to prevent the pressure from increasing to a high pressure over the set value. Furthermore, the first refrigerant dispersed in the expansion tank (220) is joined to the inflow end side of the first compressor (211).

On the other hand, the second cooling part (260) comprises a second compressor (261) for compressing the second refrigerant. Also, the second cooling part (260) comprises a second condenser (263) for heat exchange between the second refrigerant discharged from the second compressor (261) and the cooling water (PCW) supplied from the outside. Furthermore, the second cooling part (260) comprises a second electronic expansion valve (265) which is positioned between the second condenser (263) and the first condenser (213) and to which the second refrigerant discharged from the second condenser (263) is introduced.

In summary, the temperature control unit (200) is provided such that the heat exchange between the first refrigerant passing through the first compressor (211) and the second refrigerant passing through the second electronic expansion valve (265) is performed in the first condenser (213).

In addition, the first refrigerant heat-exchanged in the first condenser (213) is introduced into the evaporator (230) alone. At this time, the first refrigerant is heat-exchanged with the air in the chamber (20) during a process of passing through the evaporator (230), and then is discharged to the first compressor (211) side.

The temperature control unit (200) may cool the air passing through the evaporator (230) by the blowing unit (100) to lower the temperature in the chamber (20) or to control the temperature in response to the heat load in the chamber (20), by inflating the cold first refrigerant in the evaporator (230) through the evaporator (230) disposed on the second side surface (22) of the chamber (20).

On the other hand, the first cooling part (210) may comprise a second branch line (232) branched between the first condenser (213) and the first electronic expansion valve (215) and connected to the inflow end side of the first compressor (211). Also, the second branch line (232) is provided with a third electronic expansion valve (231). At this time, if the third electronic expansion valve (231) is opened, the first refrigerant passes through the third electronic expansion valve (231) along the second branch line (232), and then is joined into the inflow end of the first compressor (211). Accordingly, by raising the temperature of the first compressor (211), the oil in the first compressor (211) can be prevented from being carbonized.

Also, the first cooling part (210) may comprise a third branch line (234) branched between the first compressor (211) and the first condenser (213) and connected to be joined between the first electronic expansion valve (215) and the inflow end (IN) of the evaporator (230). The third branch line (234) may be provided with a fourth electronic expansion valve (233). Accordingly, the first refrigerant discharged from the first compressor (211) to pass through the fourth electronic expansion valve (215) and the first refrigerant passing through the first electronic expansion valve (215) may be joined to control the temperature of the first refrigerant introduced into the inflow end (IN) of the evaporator (230).

Furthermore, the second cooling part (260) may comprise a fourth branch line (284) branched between the second condenser (265) and the first condenser (213) (or second electronic expansion valve) and connected to the inflow end side of the second compressor (261), and the fourth branch line (284) may be provided with a fifth electronic expansion valve (283). Accordingly, if the fifth electronic expansion valve (283) is opened, after at least a part of the second refrigerant discharged from the second condenser (265) does not pass through the second electronic expansion valve (265) and is branched along the fourth branch line (284) to pass through the fifth electronic expansion valve (283), it may be joined with the second refrigerant discharged from the first condenser (213) to be introduced into the second compressor (261).

Referring to FIG. 5, the reference numeral 217 in the first cooling part (210) denotes a first oil separator, 244 and 245 each denote a pressure gauge, 243 denotes a dual press switch, 216 denotes a press transmitter, 241 denotes a first receiver, 242 denotes a first filter drier, and 251 denotes a rotalock connector. The respective components are components that are commonly used in a cooling cycle, whereby the detailed description is omitted.

In addition, the reference numeral 263 in the second cooling part denotes a second oil separator, 267 denotes a sight glass for observing the refrigerant flow, 270 denotes a cooling water circulation line introduced into the second condenser (263) and discharged from the second condenser (263), 271 and 272 each denote a solenoid valve provided in the cooling water circulation line, 291 denotes a second receiver, 292 denotes a second filter drier, 293 denotes a dual press switch, 294 and 295 each denote a pressure gauge, 313 denotes a drain pan, and 312 denotes a drain valve.

Also, as described above, in this document, each electronic expansion valve can be controlled proportionally depending on the temperature of the test chamber (20).

In addition, for example, the first refrigerant may be R-23 and the second refrigerant may be R-404.

The preferred embodiments of the present invention as described above are disclosed for exemplary purpose, where those skilled in the art having ordinary knowledge for the present invention can make various corrections, modifications and additions within idea and scope of the present invention, and such a correction, modification and addition should be considered as falling within the scope of the following claims.

### EXPLANATION OF REFERENCE NUMERALS

1: burn-in tester
20: test chamber
30: blast fan (FIGS. 1 and 2)
40: control part
41: control panel
100: blowing unit
110: blast fan (FIGS. 3 and 4)
200: temperature control unit

What is claimed is:

1. A burn-in tester for testing a semiconductor device loaded on a test board, wherein the burn-in tester comprises:
a board chamber provided to accommodate the test board;
a test chamber having an accommodation space for accommodating a tester substrate, a first side surface forming the accommodation space and a second side surface opposite to the first side surface, which is provided such that the air introduced into the accommodation space through the first side surface passes through the accommodation space to be discharged out of the accommodation space through the second side surface;
a blowing unit located on the first side surface side of the test chamber and including a plurality of blast fans for generating an air flow from the first side surface side to the second side surface side; and
a temperature control unit provided to control the temperature in the test chamber using a refrigerant circulation cycle and equipped with an evaporator located on the second side surface side of the test chamber.

2. The burn-in tester according to claim 1, wherein
the blowing unit is provided with at least two blast fans at different positions along at least one direction of the width direction and the height direction of the first side surface.

3. The burn-in tester according to claim 2, wherein
the blowing unit comprises a plurality of temperature sensors each disposed to measure temperatures of a plurality of different regions in the accommodation space, and
the plurality of blast fans are provided to be controlled individually depending on the measurement results of the plurality of temperature sensors.

4. The burn-in tester according to claim 1, wherein the temperature control unit comprises:
a first cooling part including a first compressor for compressing a first refrigerant discharged from the discharge end of the evaporator, a first condenser, and a first electronic expansion valve positioned between the first condenser and the inflow end of the evaporator and provided such that the first refrigerant passing through the first electronic expansion valve is introduced into the inflow end of the evaporator; and
a second cooling part including a second compressor for compressing a second refrigerant, a second condenser for heat exchange of the second refrigerant and cooling water, and a second electronic expansion valve positioned between the second condenser and the first condenser, and
is provided such that the heat exchange between the first refrigerant passing through the first compressor and the second refrigerant passing through the second electronic expansion valve is performed in the first condenser.

5. The burn-in tester according to claim 4, wherein
the first cooling part comprises a first branch line branched between the first compressor and the first condenser and connected to the inflow end side of the first compressor, and
the first branch line is provided with an expansion tank and one or more valves provided at the inflow end side of the expansion tank, respectively.

6. The burn-in tester according to claim 4, wherein
the first cooling part comprises a second branch line branched between the first condenser and the first electronic expansion valve and connected to the inflow end side of the first compressor, and
the second branch line is provided with a third electronic expansion valve.

7. The burn-in tester according to claim 4, wherein
the first cooling part comprises a third branch line branched between the first compressor and the first condenser and connected to be joined between the first electronic expansion valve and the inflow end of the evaporator, and
the third branch line is provided with a fourth electronic expansion valve.

8. The burn-in tester according to claim 4, wherein
the second cooling part comprises a fourth branch line branched between the second condenser and the first condenser and connected to the inflow end side of the second compressor, and
the fourth branch line is provided with a fifth electronic expansion valve.

9. The burn-in tester according to claim 1, further comprising
a control part for controlling each of the blowing unit and the temperature control unit depending on the temperature inside the test chamber.
